(19) United States
(12) Patent Application Publication
(10) Pub. No.: US 2013/0216708 A1
(43) Pub. Date: Aug. 22, 2013

(54) PRECURSOR EVAPORATORS AND METHODS OF FORMING LAYERS USING THE SAME

(71) Applicant: SAMSUNG ELECTRONICS CO., LTD., (US)

(72) Inventor: Seok YUN, Seoul (KR)

(73) Assignee: SAMSUNG ELECTRONICS CO., LTD., Suwon-si (KR)

(21) Appl. No.: 13/664,552

(22) Filed: Oct. 31, 2012

(30) Foreign Application Priority Data
Feb. 20, 2012 (KR) 10-2012-0016818

(51) Int. Cl. C23C 16/448; F17D 3/00; C23C 16/455

(52) U.S. Cl. 427/248.1; 137/602

(57) ABSTRACT

An evaporator includes a main body, an evaporation space therein, a precursor inlet through which a precursor is provided into a portion of the first evaporation space, a carrier gas inlet through which a carrier gas is provided thereinto, and an outlet through which the precursor is emitted. The evaporation space includes a first evaporation space and a second evaporation space in communication therewith. The first evaporation space has a conical shape portion and the second evaporation space has a cylindrical shape portion. The portion of the first evaporation space into which the precursor is provided corresponds to an apex of the conical shape portion. The carrier gas inlet penetrates the main body in a substantially tangential direction with respect to a sidewall of the first evaporation space at the conical shape portion. The outlet is in fluid communication with an end portion of the second evaporation space.

### CLAIM OF PRIORITY

This application claims priority under 35 USC §119 to Korean Patent Application No. 10-2012-0016818, filed on Feb. 20, 2012 in the Korean Intellectual Property Office, the contents of which are herein incorporated by reference in their entirety.

### BACKGROUND

1. Field

Apparatuses and methods consistent with exemplary embodiments relate to precursor evaporators and forming layers using the same, and more particularly, to precursor evaporators using carrier gases and forming layers using the same.

2. Description of the Related Art

Various types of deposition processes, e.g., chemical vapor deposition (CVD) process, atomic layer deposition (ALD) process, physical vapor deposition (PVD) process, etc. may be used in forming layers of semiconductor devices such as dielectric layers, conductive layers, etc. Before performing such deposition processes, liquid precursors may be evaporated and provided onto an object such as a substrate or wafer. Thus, evaporators for evaporating the liquid precursors are needed.

The liquid precursors are, preferably but not necessarily, uniformly evaporated in an evaporator and provided onto an object. If some of the liquid precursors are not evaporated or if some of the evaporated precursors are recondensed in the evaporator, e.g., at a nozzle of the evaporator, quality of layers formed using the precursors may be deteriorated.

### SUMMARY

One or more exemplary embodiments provide a precursor evaporator for forming a layer of a good quality.

One or more exemplary embodiments provide a method of forming a layer of a good quality using the precursor evaporator.

According to an aspect of an exemplary embodiment, there is provided an evaporator. The evaporator may include a main body, an evaporation space comprising first and second evaporation spaces in the main body, a precursor inlet through which a precursor is provided into a front portion of the first evaporation space, a carrier gas inlet through which a carrier gas is provided into the first evaporation space, and an outlet through which the precursor is emitted. The first evaporation space may be in fluid communication with a second evaporation space. The first evaporation space may have a conical shape portion and the second evaporation space may have a hollow cylindrical shape portion. The front portion of the first evaporation space corresponds to an apex of the conical shape portion. The carrier gas inlet may penetrate the main body, extends in a substantially tangential direction with respect to a sidewall of the first evaporation space at the conical shape portion, and may include a first carrier gas inlet and a second carrier gas inlet. The outlet is in fluid communication with an end portion of the second evaporation space.

The evaporator may further include a heater surrounding the main body.

The main body may include stainless steel.

The precursor inlet may penetrate the main body and be in fluid communication with the front portion of the first evaporation space.

A contact angle between the precursor inlet and the sidewall of the first evaporation space at the conical shape portion may be in a range of about 105 to about 120°.

A line connecting end portions of the first carrier gas inlet and the second carrier gas inlet may correspond to a diameter of a cross-section of the first evaporation space at the conical shape portion.

The outlet may include a protrusion extending toward an inside of the second evaporation space.

The outlet may be detachably inserted into the inside of the second evaporation space.

A ratio of a diameter of the second evaporation space at the hollow cylindrical portion to a diameter of the outlet may be in a range of about 5 to about 8.

An inner wall of the evaporation space may be treated, thereby becoming liquid-repellent.

The evaporator may further include a liquid-repellent layer on the inner wall of the evaporation space.

The liquid-repellent layer may include a fluorine substituted silane.

The evaporation space may have minute bumps on the inner wall thereof.

According to an aspect of another exemplary embodiment, there is provided a method of forming a layer. In the method, a substrate is loaded into a process chamber. A carrier gas heated to a given temperature range is provided into a first evaporation space via at least one carrier gas inlet to form a carrier gas cyclone. The first evaporation space may have a conical shape portion, and the carrier gas inlet may extend in a substantially tangential direction with respect to a sidewall of the first evaporation space at the conical shape portion. A precursor may be provided to a front portion of the first evaporation space corresponding to an apex of the conical shape. The precursor is evaporated by circulating the precursor via the carrier gas cyclone in a second evaporation space in fluid communication with the first evaporation space. The evaporated precursor is provided onto the substrate in the process chamber via an outlet at an end portion of the evaporator.

The outlet may include a protrusion extending toward an inside of the second evaporation space so that a non-evaporated portion of precursor may be trapped at the protrusion.

In an evaporator in accordance with exemplary embodiments, an evaporation space confined in the evaporator may include a conical first evaporation space and a hollow cylindrical second evaporation space. A carrier gas cyclone may be generated in the first evaporation space by at least one carrier gas inlet extending in a substantially tangential direction with respect to a sidewall of the conical first evaporation space at a conical shape portion. A precursor provided into the first evaporation space may form a cyclone by the carrier gas cyclone, and may circulate along the inner wall of a second evaporation space to be uniformly evaporated. Additionally, the inner wall of the evaporation space may be treated, thereby becoming liquid-repellent, and thus, the precursor droplets may be prevented from being adsorbed to the inner wall of the evaporation space. Furthermore, an outlet having a protrusion extending toward an inside of the second evaporation space may be formed at an end portion of the evaporation space. A non-evaporated portion of the precursor may be trapped at the protrusion, so that an only evaporated portion of the precursor may pass through the outlet.

### BRIEF DESCRIPTION OF THE DRAWINGS

Exemplary embodiments will be more clearly understood from the following detailed description taken in conjunction with the accompanying drawings. FIGS. 1 to 16 represent non-limiting, exemplary embodiments as described herein.

FIG. 1 is a diagram illustrating a deposition apparatus including a precursor evaporator in accordance with an exemplary embodiment;

FIG. 2 is a cross-sectional view of an evaporator in accordance with an exemplary embodiment;

FIG. 3 is a cross-sectional view cut along the line I-II in FIG. 2 in accordance with an exemplary embodiment;

FIG. 4 is an enlarged cross-sectional view of a region A of FIG. 2 in accordance with an exemplary embodiment;

FIG. 5A is an enlarged cross-sectional view of a region A of FIG. 2 in accordance with another exemplary embodiment, and FIG. 5B is an enlarged cross-sectional view of a region A when no liquid-repellent layer is formed;

FIG. 6 is an enlarged cross-sectional view of a region A of FIG. 2 in accordance with still another exemplary embodiment;

FIG. 7 is a flowchart illustrating a method of forming a layer in accordance with an exemplary embodiment;

FIGS. 8 to 14 are cross-sectional views illustrating a method of manufacturing a semiconductor device in accordance with an exemplary embodiment; and

FIGS. 15 to 19 are cross-sectional views illustrating a method of manufacturing a semiconductor device in accordance with another exemplary embodiment.

### DESCRIPTION

Various exemplary embodiments will be described more fully hereinafter with reference to the accompanying drawings. The inventive concept may, however, be embodied in many different forms and should not be construed as limited to the exemplary embodiments set forth herein. Rather, these exemplary embodiments are provided so that this description will be thorough and complete, and will fully convey the scope of the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

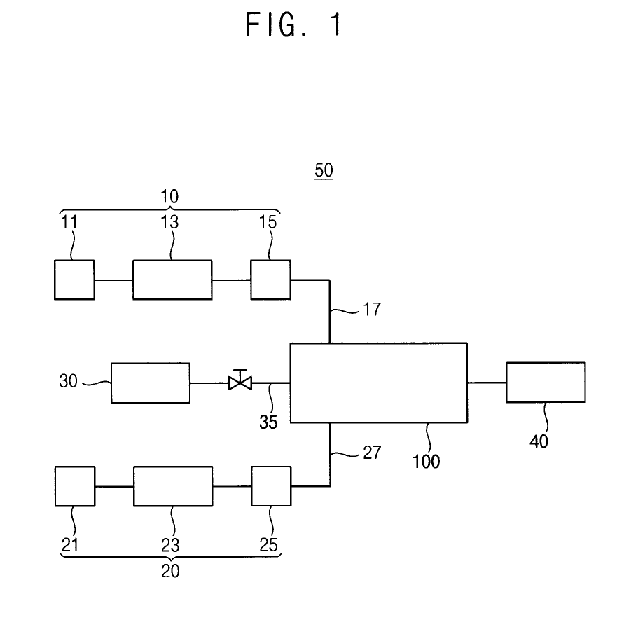

FIG. 1 is a diagram illustrating a deposition apparatus including a precursor evaporator in accordance with an exemplary embodiment.

Referring to FIG. 1, a deposition apparatus 50 may include a precursor supplier 30, a first carrier gas supplier 10, a second carrier gas supplier 20, an evaporator 100 and a process chamber 40.

The precursor supplier 30 may provide precursors serving as a source for forming various layers, e.g., a dielectric layer, an insulation layer or a conductive layer, not being limited thereto, into the evaporator 100. According to an exemplary embodiment, a liquid source may be provided into the evaporator 100 by the precursor supplier 30.

A precursor may be a composition including a central metal and a ligand bonded thereto.

For example, the precursor may be tetrakis-ethylmethylamido-zirconium (TEMAZ), tetrakis-ethylmethylamido-hafnium, tetrakis-diethylamido-zirconium (TDEAZ), tetrakis-diethylamido-hafnium, tetrakis-dimethylamido-zirconium (TDMAZ), tetraethyl orthosilicate (TEOS), tetrakis-dimethylamido-titanium, tetrakis-diethylamido-titanium, tetrakis-diethylamido-titanium, trimethyl aluminum, dimethyl aluminum or composition thereof.

The precursor may be in a liquid state at a room temperature. Alternatively, the precursor may be in a solid state at a room temperature, and in this case, the precursor may be used after being solved in an organic solution, e.g., alcohol, tetrahydrofuran, an ether group, or a composition thereof, not being limited thereto.

The precursor supplier 30 may be connected to the evaporator 100 via a precursor transport line 35. According to an exemplary embodiment, a flow rate controller may be installed at the transport line 35.

The first carrier gas supplier 10 may include a first carrier gas container 11, a first carrier gas flow rate controller 13 and a first carrier gas heater 15. The order of location of the first carrier gas flow rate controller 13 and the first carrier gas heater 15 may not be limited thereto.

The first carrier gas supplier 10 may be in fluid communication with the evaporator 100 via a first carrier gas transport line 17.

According to an exemplary embodiment, a first carrier gas contained in the first carrier gas container 11 may be provided into the evaporator 100 by the first carrier gas flow rate controller 13 and the first carrier gas heater 15. The first carrier gas may include an inactive gas, e.g., nitrogen, argon, helium or a composition thereof, not being limited thereto.

The second carrier gas supplier 20 may include a second carrier gas container 21, a second carrier gas flow rate controller 23 and a second carrier gas heater 25. The order of location of the second carrier gas flow rate controller 23 and the second carrier gas heater 25 may not be limited thereto.

The second carrier gas supplier 20 may be in fluid communication with the evaporator 100 via a second carrier gas transport line 27.

According to an exemplary embodiment, a second carrier gas contained in the second carrier gas container 21 may be provided into the evaporator 100 by the second carrier gas flow rate controller 23 and the second carrier gas heater 25. The second carrier gas may include an inactive gas, e.g., nitrogen, argon, helium or a composition thereof, not being limited thereto. According to an exemplary embodiment, the second carrier gas may be substantially the same as the first carrier gas.

FIG. 1 shows the first and second carrier gas containers 11 and 21 that are separate from each other, however, a single carrier gas container (not shown) may be provided instead of the separate first and second carrier gas containers 11 and 21.

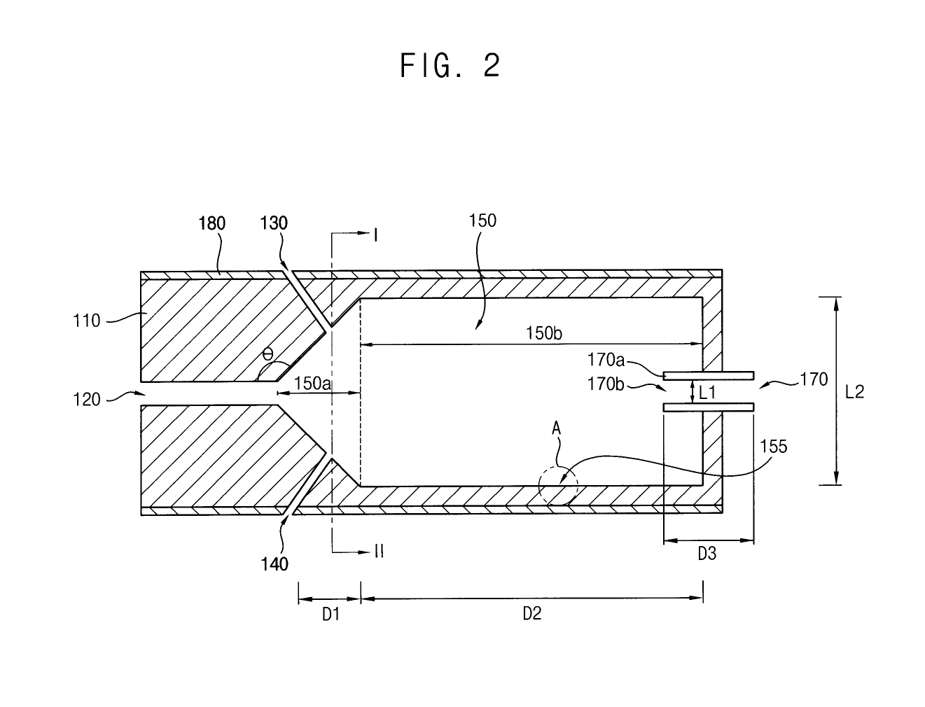

The structure and shape of the evaporator 100 may be illustrated in detail with reference to FIG. 2.

The process chamber 40 may provide a space in which evaporated precursor may be provided and a layer may be deposited on an object. According to an exemplary embodiment, the process chamber 40 may be a CVD process chamber or an ALD process chamber.

In the process chamber 40, there may be an upper electrode (not shown), a lower electrode (not shown), a shower head (not shown), etc. The shower head may give off the evaporated precursor into the space. The object may include, e.g., a wafer. The layer may be deposited on the object by the power generated between the upper and lower electrodes. A vacuum pump (not shown) may be further provided at the process chamber 40.

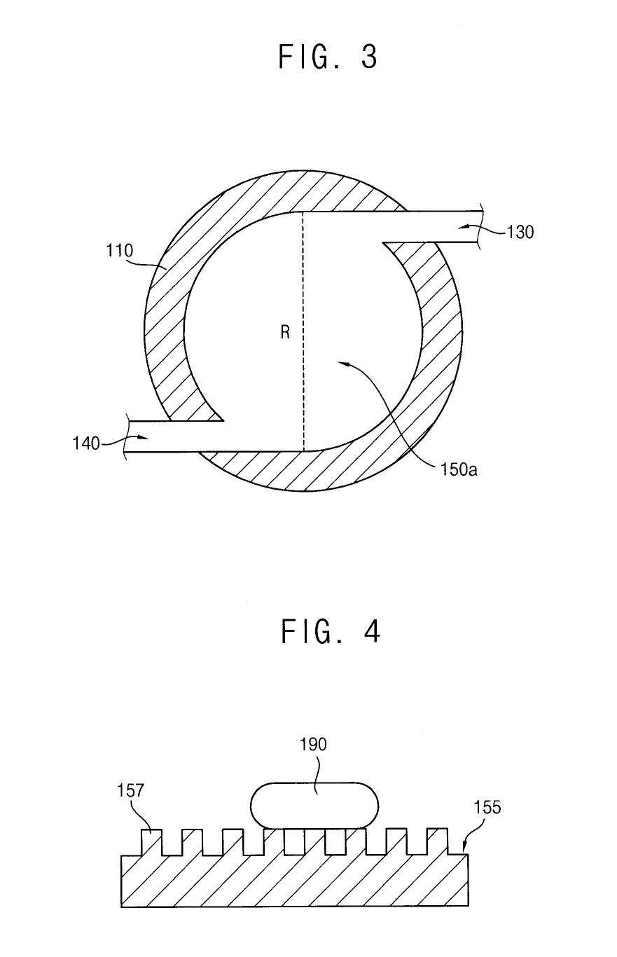

FIG. 2 is a cross-sectional view illustrating an evaporator in accordance with an exemplary embodiment, and FIG. 3 is a cross-sectional view cut along the line I-II in FIG. 2 in accordance with an exemplary embodiment.

Referring to FIG. 2, an evaporator 100 may include a main body 110, a precursor inlet 120, a first carrier gas inlet 130, a second carrier gas inlet 140 and an outlet 170. The evaporator 100 may have an evaporation space 150 in which a precursor may be evaporated and move. The evaporator 100 may further include a heater 180 enclosing the main body 110.

The main body 110 may include a metal having a high thermal conductivity. For example, the main body 110 may include stainless steel.

A precursor provided into the evaporation space 150 may be evaporated and guided toward the outlet 170 by a carrier gas. In exemplary embodiments, the evaporation space 150 may include a first evaporation space 150a and a second evaporation space 150b.

The first evaporation space 150a may be in fluid communication with the precursor inlet 120, the first carrier gas inlet 130 and the second carrier gas inlet 140. According to an exemplary embodiment, the first evaporation space 150a may have a conical shape. For example, the first evaporation space 150a may have a horizontal cross-section of a circular shape and an area of the horizontal cross-section may increase from a portion of the first evaporation space 150a adjacent to the precursor inlet 120 toward a portion thereof adjacent to the outlet 170. Due to the shape of the first evaporation space 150a, a cyclone of carrier gases provided from the first carrier gas inlet 130 and the second carrier gas inlet 140 may be generated in the first evaporation space 150a and propagate to the second evaporation space 150b. However, an entire portion of the first evaporation space 150a does not have to take the conical shape. According to an exemplary embodiment, only a portion where the first and second carrier gas inlets 130 and 140 are disposed may take the conical shape to generate a cyclone of carrier gases provided from the first and second carrier gas inlets 130 and 140. Further, the shape of the first evaporation space 150a is not limited to the conical shape. According to an exemplary embodiment, a different shape having a curved surface may constitute the first evaporation space so that the carrier gases provided from the first and second carrier gas inlets 130 and 140 can circulate to generate a cyclone.

The second evaporation space 150b may have a hollow cylindrical shape. The second evaporation space 150b may have a length at which the carrier gas cyclone may sufficiently progress and circulate the precursor so that the precursor may be evaporated. When a length of the first evaporation space 150a is denoted as “D1” and a length of the second evaporation space 150b is denoted as “D2,” D2/D1 may be about 8 to about 12. If D2/D1 is less than about 8, the precursor may not be sufficiently circulated and evaporated. If D2/D1 is more than about 12, an intensity of the cyclone such as an angular velocity or a centrifugal force may be weakened at an end portion of the second evaporation space 150b adjacent to the outlet 170 so that the evaporated precursor may be recondensed. According to an exemplary embodiment, the first evaporation space 150a may have a length D1 of about 8 nm to about 15 nm, and the second evaporation space 150b may have a length D2 of about 80 nm to about 120 nm. An entire portion of the second evaporation space 150b does not have to have the hollow cylindrical shape. Also, the shape of the second evaporation space 150b is not limited to the hollow cylindrical shape as long as the carrier gas cyclone can sufficiently progress to evaporate the precursor.

The precursor inlet 120 may be connected to the precursor transport line 35 of the deposition apparatus 50 in FIG. 1. Thus, a liquid precursor may be given off to the evaporation space 150 via the precursor inlet 120. As shown in FIG. 2, the precursor inlet 120 may be buried in the main body 110. Thus, a heat transfer from the main body 110 of which a temperature has been increased by the heater 180 to the precursor inlet 120 may be efficiently performed.

The precursor inlet 120 and a sidewall of the first evaporation space 150a may have a given inclination angle θ therebetween as shown in FIG. 2. A liquid precursor transported via the precursor inlet 120 may be heated by a heat transferred from the main body 110. A space in which the precursor may move may be enlarged by changing the inclination angle θ when the precursor enters the first evaporation space 150a, and thus the precursor may be dispersed to be changed into mist due to the decrease of pressure.

The inclination angle θ may be selected in consideration of the efficiency of the dispersion of the liquid precursor and/or the efficiency of the generation of the cyclone of the carrier gas provided through the first carrier gas inlet 130 and the second carrier gas inlet 140. According to an exemplary embodiment, the include angle θ may be in a range of about 105° to about 120°. If the inclination angle θ is less than about 105°, the conical space for forming the cyclone may not be sufficient. If the inclination angle θ is more than about 120°, the precursor may not be dispersed sufficiently in the first evaporation space 150a.

The first and second carrier gas inlets 130 and 140 may be in fluid communication with the first evaporation space 150a, and a carrier gas may be provided by the first and second carrier gas inlets 130 and 140. The carrier gas may include an inactive gas, e.g., helium, argon, nitrogen or a composition thereof, not being limited thereto.

The first and second carrier gas inlets 130 and 140 may be arranged so that the cyclone of the carrier gas may be efficiently generated. According to an exemplary embodiment, as shown in FIG. 3, the first and second carrier gas inlets 130 and 140 may penetrate the main body 110 from the first and second carrier gas supplier 10 and 20, respectively, and extend in a substantially tangential direction with respect to a sidewall of the first evaporation space 150a. A line connecting end portions of the first and second carrier gas inlets 130 and 140 may correspond to a diameter R of a cross-section of the first evaporation space 150a. Thus, the carrier gas provided from the first and second carrier gas inlets 130 and 140 may circulate along the sidewall of the first evaporation space 150a and generate a cyclone effectively.

According to an exemplary embodiment, the carrier gas may be heated when provided into the first evaporation space 150a by the carrier gas heaters 15 and 25 (FIG. 1), thereby forming a cyclone. The cyclone may propagate to the second evaporation space 150b and circulate so that the second evaporation space 150b may have a uniform temperature therein. Accordingly, the precursor may be prevented from being recondensed locally in the evaporation space 150. The cyclone may form a circulation stream along the sidewall of the evaporation space 150 and the precursor may also form a circulation stream and move along the sidewall of the evaporation space 150. Thus, the precursor may be evaporated effectively in the evaporation space 150.

Remaining droplets of the precursor when the precursor moves along the sidewall of the evaporation space 150 may be adsorbed to an inner wall of the evaporation space 150 and may contaminate the evaporation space 150. Particularly, when the droplets of the precursor remain on the inner wall of the evaporation space 150 and are solidified, the inner wall of the evaporation space 150 may be contaminated, and thus, the evaporator 100 needs cleaning or being replaced.

In exemplary embodiments, the inner wall of the evaporation space 150 may be treated so that the inner wall thereof may become liquid-repellent. In this case, the precursor droplets may not be adsorbed to the inner wall of the evaporation space 150 and may be easily separated therefrom, so that the evaporator 100 may be used for a long time. Additionally, the precursor droplets may be provided into the cyclone and circulate so that the efficiency of the evaporation may be enhanced.

FIG. 4 is an enlarged cross-sectional view of a region A of FIG. 2 in accordance with an exemplary embodiment.

Referring to FIG. 4, an inner wall 155 of the evaporation space 150 may be treated, thereby having a plurality of minute bumps 157. For example, the inner wall 155 may have a cogwheel shape. Thus, when a precursor droplet 190 makes contact with the inner wall 155, the inner wall 155 may have a reduced contact area with the precursor droplet 190 when compared to an inner wall having a flat surface. Thus, the precursor droplet 190 may be prevented from being adsorbed to the inner wall 155 and solidified.

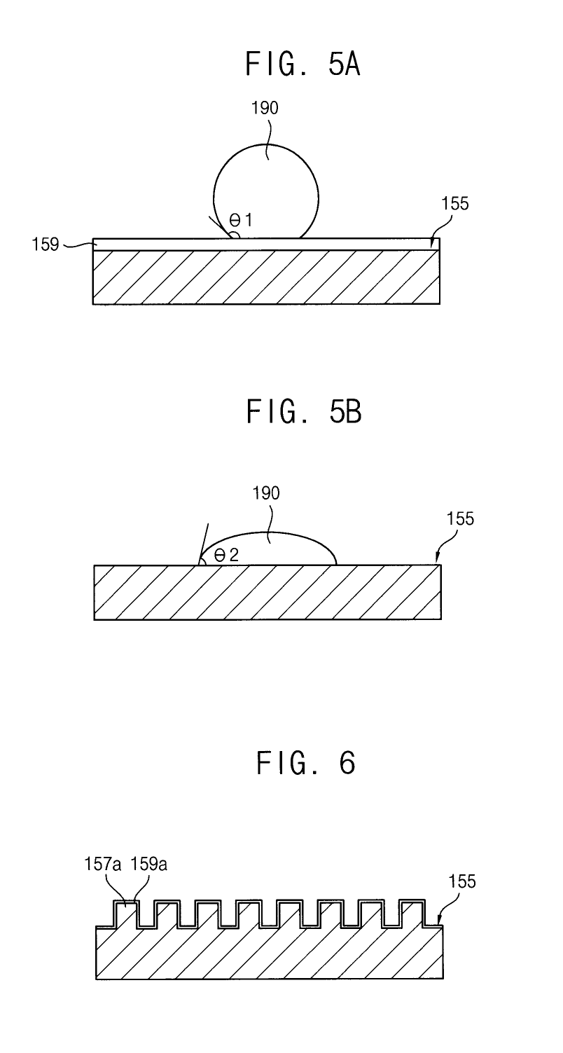

FIG. 5A is an enlarged cross-sectional view of a region A of FIG. 2 in accordance with another exemplary embodiment. FIG. 5B is an enlarged cross-sectional view of a region A when no liquid-repellent layer is formed.

Referring to FIG. 5A, a liquid-repellent layer 159 may be formed on the inner wall 155 of the evaporation space 150. The liquid-repellent layer 159 may be formed on the inner wall 155 of the evaporation space 150 using a liquid-repellent material by a spray coating process. In this case, the precursor droplet 190 and the liquid-repellent layer 159 may make a first contact angle θ1 therebetween. As shown in FIG. 5B, if there is no liquid-repellent layer on the inner wall 155 of the evaporation space 150, the precursor droplet 190 and the liquid-repellent layer 159 may make a second contact angle θ2 therebetween. Due to the repellent property of the liquid-repellent layer 159, the first contact angle θ1 may be greater than the second contact angel θ2. That is, the liquid-repellent layer 159 may have a lower surface energy and a lower wettability than those of the inner wall 155 of the evaporation space 150, respectively. Thus, the precursor droplet 190 may be prevented from being adsorbed to and contaminating the inner wall 155 of the evaporation space 150.

According to an exemplary embodiment, the liquid-repellent layer 159 may include a material that may make a first contact angel θ1 with the precursor droplet 190 equal to or larger than about 90°. For example, the liquid-repellent layer 159 may include a fluorine substituted silane. The fluorine substituted silane may be represented as following chemical formula 1.

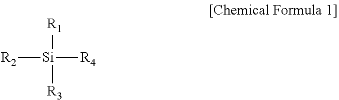

In chemical formula 1, R₁, R₂, R₃ and R₄ each independently may be selected from the group consisting of hydrogen, a C₁-C₂₀ alkyl group, a C₁-C₂₀ alkoxy group, halogen, an amino group or a hydroxyl group. According to an exemplary embodiment, at least one of R₁ to R₄ may be a C₁-C₂₀ alkyl group or a C₁-C₂₀ alkoxy group. The C₁-C₂₀ alkyl group or the C₁-C₂₀ alkoxy group may be substituted with at least one fluorine atom.

According to an exemplary embodiment, the fluorine substituted silane may include a polysiloxane represented by following chemical formula 2.

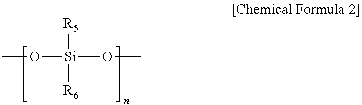

In chemical formula 2, R₅ and R₆ each independently may be selected from the group consisting of hydrogen, a C₁-C₂₀ alkyl group, a C₁-C₂₀ alkoxy group, halogen, an amino group or a hydroxyl group. According to an exemplary embodiment, at least one of R₅ and R₆ may be a C₁-C₂₀ alkyl group or a C₁-C₂₀ alkoxy group. The C₁-C₂₀ alkyl group or the C₁-C₂₀ alkoxy group may be substituted with at least one fluorine atom. N may be an integer equal to or greater than 2.

According to an exemplary embodiment, the fluorine substituted silane may include a cyclic polysiloxane having repeating units represented by following chemical formula 3.

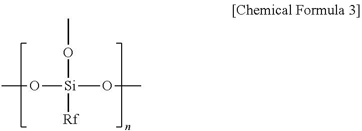

In chemical formula 3, R_{f} may include a C₁-C₂₀ alkyl group or a C₁-C₂₀ alkoxy group in which at least one carbon is substituted with a fluorine. N may be an integer equal to or greater than 4. For example, the cyclic polysiloxane having the repeating units represented by following chemical formula 3 may be represented by following chemical formula 4.

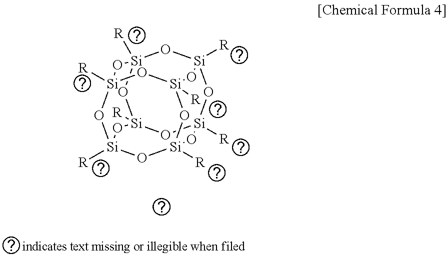

FIG. 6 is an enlarged cross-sectional view of a region A of FIG. 2 in accordance with still another exemplary embodiment.

Referring to FIG. 6, the inner wall 155 of the evaporation space 150 may include minute bumps 157a, and a liquid-repellent layer 159a may be formed thereon. In this case, the contact area between the inner wall 155 and the precursor droplet may decrease due to the minute bumps 157a, and the contact angle between the inner wall 155 and the precursor droplet may increase due to the liquid-repellent layer 159a. Thus, the adhesion of the precursor droplet to the inner wall 155 of the evaporation space 150 may be effectively prevented or reduced.

According to an exemplary embodiment, the inner wall 155 of the evaporation space 150 may be treated to be liquid-repellent by an electronic beam treatment or a plasma treatment. Owing to the electronic beam treatment or the plasma treatment, a surface energy of the inner wall 155 may be decreased, and thus, the inner wall 155 may have the liquid-repellent property.

Referring to FIG. 2 again, the evaporator 100 may include the outlet 170 at an end portion of the second evaporation space 150a. In exemplary embodiments, the outlet 170 may include a protrusion 170a extending toward the inside of the second evaporation space 150a. The outlet 170 may be in fluid communication with the process chamber 40 of the evaporator 50 in FIG. 1.

The cyclone of the carrier gas and the evaporated precursor may be concentrated on an entrance 170b of the protrusion 170a, and only the evaporated precursor may enter the outlet 170 and pass by the outlet 170 with a fast flow velocity. A portion of the liquid precursor that is not evaporated may be trapped at the protrusion 170a.

According to an exemplary embodiment, the outlet 170 may be detachably inserted into a wall of the evaporator 100. Thus, after evaporation, the outlet 170 may be detached from the evaporator 100 and the solidified precursor may be cleaned, which may be simple.

A diameter of the entrance 170b of the protrusion 170a or of the outlet 170 may be represented by L1 in FIG. 2, and a diameter of the second evaporation space 150b may be represented by L2. According to an exemplary embodiment, L2/L1 (hereinafter, referred to as R_{L}) may be about 5 to about 8. If R_{L} is less than about 5, the cyclone of the precursor may not be sufficiently concentrated on the protrusion 170a of the outlet 170. If R_{L} is more than about 8, the diameter L1 of the protrusion 170a is relatively small, and thus, the flow of the evaporated precursor may be inhibited by a portion of the liquid precursor which is not evaporated and trapped at the protrusion 170a.

In FIG. 2, a length of the protrusion 170a may be represented by D3. According to an exemplary embodiment, D2/D3 that is a ratio of the length of the second evaporation space 150b to the length of the protrusion 170a may be about 7 to about 10. If D2/D3 is less than about 7, a length for the cyclone of the precursor circulating before entering the protrusion 170a may not be sufficiently assured. If D2/D3 is more than about 10, the flow velocity of the cyclone may be lowered near the protrusion 170a, so that the evaporated precursor may not be sufficiently concentrated on the entrance 170b of the protrusion 170a.

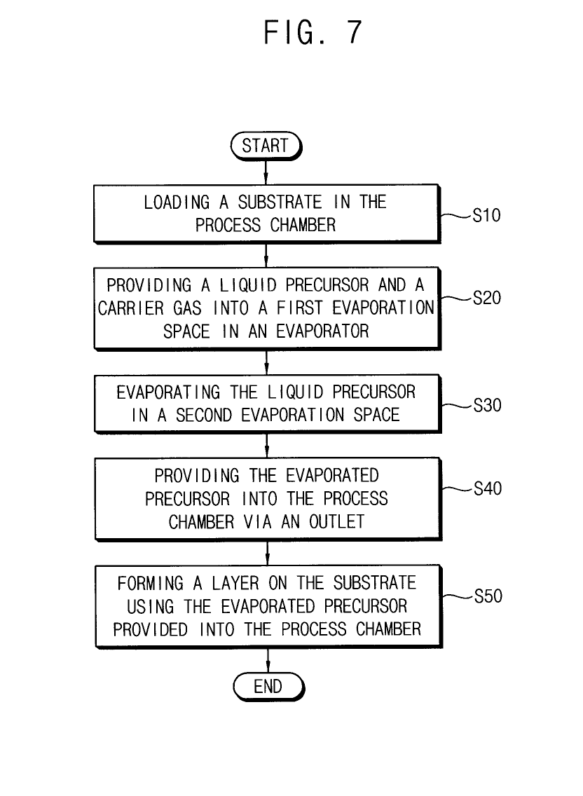

FIG. 7 is a flowchart illustrating a method of forming a layer in accordance with an exemplary embodiment. Hereinafter, the method of forming the layer may be illustrated with reference to the deposition apparatus 50 and the evaporator 100 shown in FIGS. 1 and 2.

Referring to FIG. 7, a substrate on which a layer may be formed may be loaded in the process chamber 40 (S10). The substrate may include a conductive structure, e.g., a conductive contact, a via, an electrode, etc. or an insulation layer, and may further include an opening, a contact hole in which the layer may be deposited.

The substrate may be mounted on a support or a lower electrode at a lower portion of the process chamber 40.

In step S20, a liquid precursor and a carrier gas may be provided into the first evaporation space 150a of the evaporator 100. The inner wall 155 of the evaporation space 150 may be set to a temperature of about 130 to about 250° C. The temperature may be controlled by a heater 180 surrounding the main body 110 of the evaporator 100.

The examples of the precursor and the carrier gas have been described above. According to an exemplary embodiment, a viscosity of the precursor may be controlled to have about 0.01 to about 10 mPa/s. If the viscosity is more than about 10 mPa/s, the precursor may not be easily guided by the cyclone of the carrier gas and may be easily adsorbed onto the inner wall 155 of the evaporation space 150 to contaminate the evaporator 100. If the viscosity is less than about 0.01 mPa/s, the liquidity of the precursor may be enlarged too much so that a constant circulation stream may not be generated.

The precursor may have a vapor pressure of about 10 to about 200 Torr at a temperature of about 130° C., thereby being sufficiently evaporated in the evaporation space 150.

The precursor may be provided into the first evaporation space 150a in a liquid state from the precursor supplier 30 and the precursor transport line 35 via the precursor inlet 120. The precursor may be dispersed to be changed into mist due to the decrease of pressure when the precursor enters the conical first evaporation space 150a.

The carrier gas may be provided into the first evaporation space 150a from the first and second carrier gas suppliers 10 and 20 via the first and second carrier gas inlets 130 and 140. Due to the above-illustrated layout of the first and second carrier gas inlets 130 and 140, the carrier gas may be provided in a substantially tangential direction with respect to a sidewall of the first evaporation space 150a. Thus, the carrier gas may circulate along the inner wall of the first evaporation space 150a to form a cyclone. The precursor may be guided by the carrier gas cyclone to form a circulation stream or a cyclone along the inner wall of the first evaporation space 150a. According to an exemplary embodiment, the carrier gas may be heated by the first and second carrier gas heaters 15 and 25 before entering the evaporator 100. According to an exemplary embodiment, the carrier gas may be heated to a temperature similar to that of the inner wall of the evaporation space 150. For example, the temperature of the carrier gas may be controlled in a range of about 130 to about 250° C. Thus, the precursor provided into the evaporation space 150 in a liquid state may be surrounded by the carrier gas cyclone and evaporated, and may be evaporated by contacting the inner wall 155 of the evaporation space 150. A difference of the temperature of the evaporation space 150 may be reduced so that a local recondensing may not occur and the evaporation may be uniformly performed.

The order of the provision of the precursor and the carrier gas may be changed and may not be limited. For example, the precursor and the carrier gas may be simultaneously provided into the first evaporation space 150a, or after the carrier gas, the precursor may be provided.

Referring to FIG. 7, in step S30, the precursor may be evaporated in the second evaporation space 150b. As described above, the carrier gas cyclone generated in the first evaporation space 150a may propagate into the second evaporation space 150b together with the precursor. The precursor may be guided by the carrier gas and may form a cyclone, and may be evaporated by contacting the carrier gas. The precursor together with the carrier gas may circulate along the inner wall 155 of the evaporation space 150 and may be evaporated.

According to an exemplary embodiment, the inner wall 155 of the evaporation space 150 may be treated to be liquid-repellent. Thus, some droplets of the precursor that have not been evaporated may be prevented from being adsorbed to the inner wall 155 and solidified. Even though the precursor droplets may contact the inner wall 155, the precursor droplets may be detached from the inner wall 155 by the above treatment and may be merged into the cyclone to be evaporated.

In step S40, the evaporated precursor may be provided into the process chamber 40 via the outlet 170. As described above, the evaporated precursor may form a cyclone and may be concentrated on the protrusion 170a of the outlet 170. A portion of the precursor that has not been evaporated may be trapped at the protrusion 170a, and only the evaporated precursor may enter the entrance 170b of the protrusion 170a and provided into the process chamber 40.

In step S50, a layer may be formed on the substrate using the evaporated precursor provided into the process chamber 40.

According to an exemplary embodiment, the layer may be formed by a deposition process such as a CVD process or an ALD process. The process chamber 40 may be controlled to have a proper temperature and pressure, and may be in a vacuum state by a vacuum pump.

According to an exemplary embodiment, when the precursor adsorbed to the substrate, a ligand bonded to a central metal of the precursor may depart and be emitted outside the process chamber 40 together with the carrier gas that has been provided with the precursor. The central metal may be stacked on the substrate to form a conductive layer including the metal.

According to an exemplary embodiment, a reactant may be provided into the process chamber 40 after the precursor is adsorbed onto the substrate, so that a layer, e.g., an oxide layer, a nitride layer or an oxynitride layer, not being limited thereto, may be formed. Oxygen or nitrogen atoms included in the reactant may be substituted for the ligand of the precursor so that a metal oxide layer, a metal nitride layer or a metal oxynitride layer, not being limited thereto, may be formed.

According to an exemplary embodiment, the reactant may include an oxidative material, e.g., ozone gas, oxygen gas, oxygen plasma or ozone plasma, not being limited thereto. In this case, a metal oxide layer may be formed on the substrate. For example, the metal oxide layer may include a high-k layer, e.g., a zirconium oxide layer, a hafnium oxide layer or a titanium oxide layer, not being limited thereto.

Alternatively, the reactant may include a nitrogen-containing material, e.g., ammonia gas, nitric oxide gas, nitrous oxide gas, etc. In this case, a metal nitride layer may be formed on the substrate. The metal nitride layer may include a titanium nitride layer, a tantalum nitride layer or a tungsten nitride layer, not being limited thereto, and may serve as a conductive layer in a semiconductor device.

After forming a layer on the substrate, remnants of the reactant, remnants of the precursor, and the ligand having departed from the precursor may be removed from the process chamber 40 by a purge process.

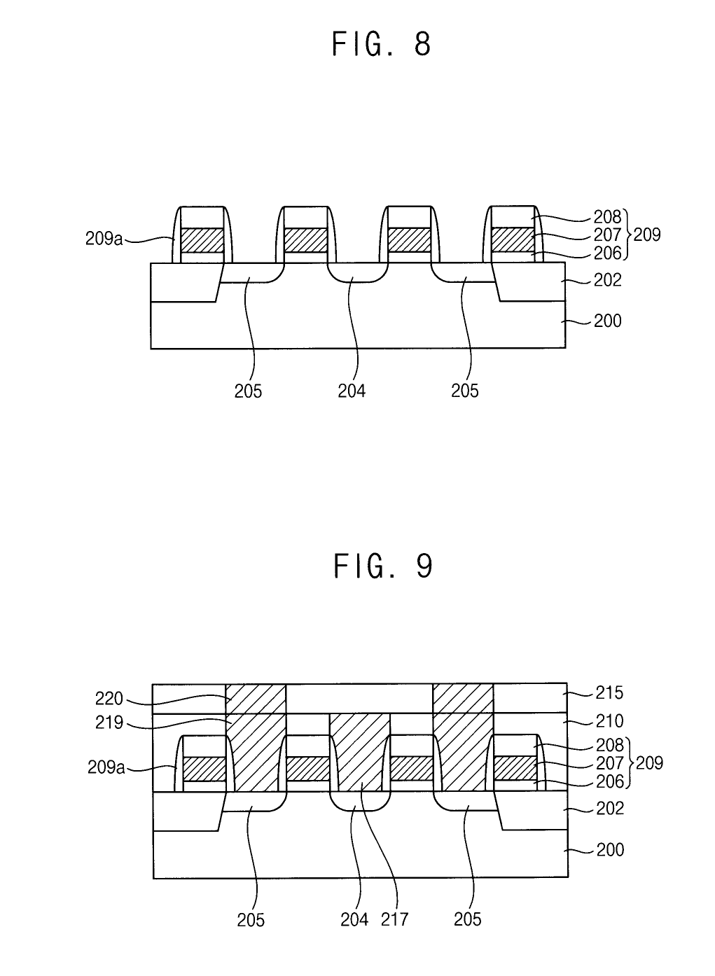

FIGS. 8 to 14 are cross-sectional views illustrating a method of manufacturing a semiconductor device in accordance with an exemplary embodiment. Particularly, FIGS. 8 to 14 may be cross-sectional views illustrating a method of manufacturing a dynamic random access memory (DRAM) device.

Referring to FIG. 8, an isolation layer 202 may be formed on a substrate 200. The substrate 200 may be a semiconductor substrate, e.g., a silicon substrate, a germanium substrate or a silicon-germanium substrate, a silicon-on-insulator (SOI) substrate or a germanium-on-insulator (GOI) substrate, not being limited thereto. The isolation layer 202 may be formed by a shallow trench isolation (STI) process.

A gate insulation layer, a gate electrode layer and a gate mask layer may be formed on the substrate 200, and patterned by a photolithography process to form a plurality of gate structures 209 each of which may include a gate insulation layer pattern 206, a gate electrode 207 and a gate mask 208 sequentially stacked on the substrate 200. The gate insulation layer may be formed to include silicon oxide or a metal oxide, the gate electrode layer may be formed to include doped polysilicon or a metal, and the gate mask layer may be formed to include silicon nitride.

An ion implantation process may be performed using the gate structures 209 as an ion implantation mask to form first and second impurity regions 204 and 205 at upper portions of the substrate 200 adjacent to the gate structures 209.

The gate structure 209 and the first and second impurity regions 204 and 205 may form a transistor. The first and second impurity regions 204 and 205 may serve as source/drain regions of the transistor.

Spacers 209a including silicon nitride may be further formed on sidewalls of the gate structures 209.

Referring to FIG. 9, a first insulating interlayer 210 may be formed on the substrate 200 to cover the gate structures 209 and the spacers 209a. The first insulating interlayer 210 may be partially removed to form first holes (not shown) exposing the impurity regions 204 and 205. According to an exemplary embodiment, the first holes may be formed to be self-aligned to the gate structures 209 and the spacers 209a.

A first conductive layer filling the first holes may be formed on the substrate 200 and the first insulating interlayer 210, and the first conductive layer may be planarized by a chemical mechanical planarization (CMP) process and/or an etch back process until a top surface of the first insulating interlayer 210 may be exposed to form first and second plugs 217 and 219 in the first holes. The first plug 217 may contact the first impurity region 204 and the second plug 219 may contact the second impurity region 205. The first conductive layer may be formed to include doped polysilicon, a metal, etc. The first plug 217 may serve as a bit line contact.

A second conductive layer (not shown) contacting the first plug 217 may be formed on the first insulating interlayer 210, and patterned to form a bit line (not shown). The first and/or second conductive layers may be formed to include doped polysilicon, a metal, or a composition thereof, not being limited thereto.

A second insulating interlayer 215 covering the bit line may be formed on the first insulating interlayer 210. The second insulating interlayer 215 may be partially removed to form second holes (not shown) exposing the second plug 219. A third conductive layer filling the second holes may be formed on the second plug 219 and the second insulating interlayer 215. The third conductive layer may be planarized by a CMP process and/or an etch back process until a top surface of the second insulating interlayer 215 may be exposed to form third plugs 220 in the second holes. The third conductive layer may be formed to include doped polysilicon, a metal, or a composition thereof, not being limited thereto. The second and third plugs 219 and 220 may serve as capacitor contacts. Alternatively, the second plug 219 may not be formed, and the third plug 220 may be formed through the first and second insulating interlayers 210 and 215 to contact the second impurity region 219.

Referring to FIG. 10, an etch stop layer 225 and a mold layer 230 may be sequentially formed on the second insulating interlayer 215, and the mold layer 230 and the etch stop layer 225 may be partially removed to form an opening 235 exposing a top surface of the third plug 220. For example, the mold layer 230 may be formed to include silicon oxide, and the etch stop layer 225 may be formed to include silicon nitride.

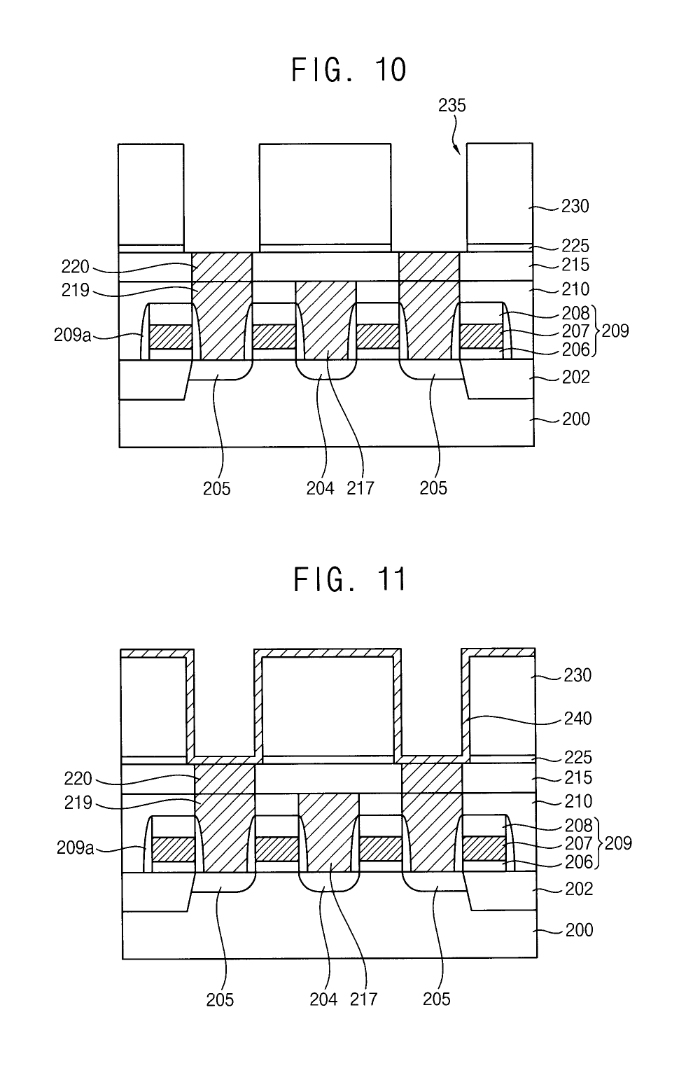

Referring to FIG. 11, a lower electrode layer 240 may be formed on the exposed top surface of the third plug 220, an inner wall of the opening 235 and a top surface of the mold layer 230. The lower electrode layer 240 may be formed by the method of forming a layer illustrated with reference to FIG. 7 using the deposition apparatus 50 and the evaporator 100 illustrated with reference to FIGS. 1 to 6.

According to an exemplary embodiment, a structure formed by the processes illustrated with reference to FIGS. 8 to 10 may be loaded into the process chamber 40. For example, a precursor including titanium such as tetrakis-dimethylamido-titanium or tetrakis-diethylamido-titanium or a precursor including tantalum may be provided into the evaporation space 150 of the evaporator 100.

As illustrated above, a carrier gas cyclone may be generated to evaporate the precursor in the evaporation space 150. The evaporated precursor may be provided via the outlet 170 into the process chamber 40 to form the lower electrode layer 240 on the structure. Ligands may depart from the central metal, e.g., titanium, tantalum or a composition thereof, not being limited thereto in the precursor and may be emitted outside of the process chamber 40 together with the carrier gas. When the central metal may be deposited on the structure, a titanium layer or a tantalum layer may be formed as the lower electrode layer 240. According to an exemplary embodiment, when a reactant, e.g., ammonia gas, nitric oxide gas, nitrous oxide gas or a composition thereof, not being limited thereto may be provided together with the evaporated precursor, a titanium nitride layer or a tantalum nitride layer may be formed as the lower electrode layer 240.

Referring to FIG. 12, a sacrificial layer (not shown) may be formed on the lower electrode layer, and the sacrificial layer and the lower electrode layer may be partially removed until a top surface of the mold layer 230 may be exposed. The sacrificial layer and the mold layer 230 may be removed to form a lower electrode 245 electrically connected to the third plug 220.

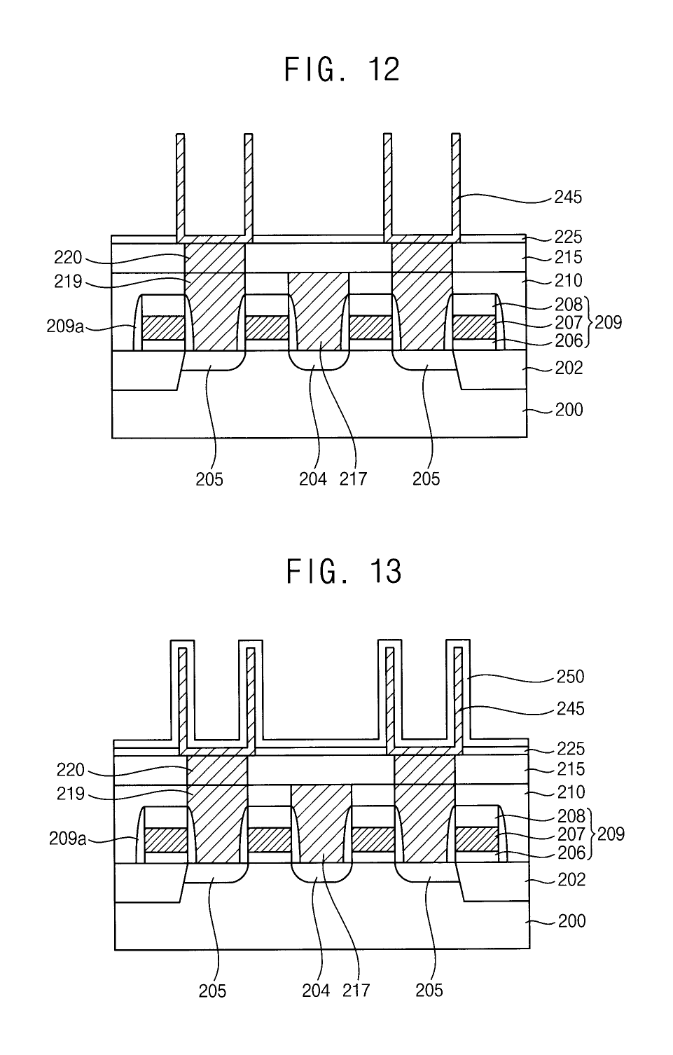

Referring to FIG. 13, a dielectric layer 250 may be formed on the etch stop layer 225 to cover the lower electrode 245. The dielectric layer 250 may be formed to include a metal oxide having a high dielectric constant. The dielectric layer 250 may be also formed by the method of forming a layer illustrated with reference to FIG. 7 using the deposition apparatus 50 and the evaporator 100 illustrated with reference to FIGS. 1 to 6.

For example, an organic metal precursor including zirconium, e.g., TEMAZ or an organic metal precursor including hafnium, e.g., tetrakis-ethylmethylamido-hafnium may be used.

An oxidative material, e.g., ozone gas, oxygen gas or a composition thereof, not being limited thereto, as a reactant may be provided when the evaporated precursor may be provided using the evaporator 100 by the above-illustrated processes. Thus, a hafnium oxide layer or a zirconium oxide layer may be formed as the dielectric layer 250.

Referring to FIG. 14, an upper electrode layer 260 may be formed on the dielectric layer 250. The upper electrode layer 260 may be formed to include a metal or a metal nitride, e.g., titanium, tantalum, tungsten, ruthenium, titanium nitride, tantalum nitride, tungsten nitride or a composition thereof, not being limited thereto. The upper electrode layer 260 may be also formed by processes substantially the same as or similar to those of the lower electrode layer 240.

Thus, a capacitor including the lower electrode 245, the dielectric layer 250 and the upper electrode 260 may be formed.

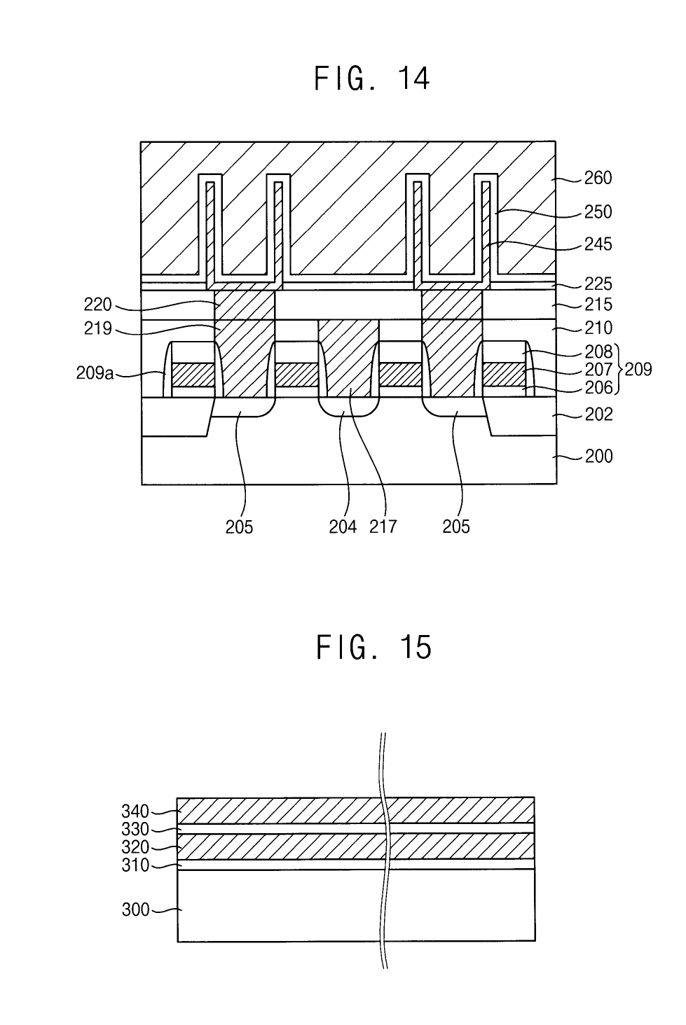

FIGS. 15 to 19 are cross-sectional views illustrating a method of manufacturing a semiconductor device in accordance with another exemplary embodiment. Particularly, FIGS. 15 to 19 may be cross-sectional views illustrating a method of manufacturing a floating gate type flash memory device, however, the inventive concept may be also applied to manufacturing various semiconductor devices such as a charge trapping type flash memory device.

Referring to FIG. 15, a tunnel insulation layer 310, a floating gate layer 320, a dielectric layer 330 and a control gate layer 340 may be sequentially formed on a substrate 300.

The tunnel insulation layer 310 may be formed to include an oxide such as silicon oxide, a nitride such as silicon nitride, or a metal nitride by a deposition process such as a CVD process, an ALD processor a sputtering process. Alternatively, the tunnel insulation layer 310 may be formed by performing a thermal oxidation process on the substrate 300.

When the tunnel insulation layer 310 is formed to include a metal oxide, the method of forming a layer illustrated with reference to FIG. 7 using the deposition apparatus 50 and an evaporator 100 illustrated with reference to FIGS. 1 to 6 may be used.

The floating gate layer 320 may be formed to include doped polysilicon and/or a metal having a high work function, e.g., tungsten, titanium, cobalt, nickel or a composition thereof, not being limited thereto by a deposition process such as a CVD process, an ALD process or a sputtering process.

The floating gate layer 320 may be formed by the method of forming a layer illustrated with reference to FIG. 7 using the deposition apparatus 50 and an evaporator 100 illustrated with reference to FIGS. 1 to 6. For example, a precursor including titanium such as tetrakis-dimethylamido-titanium, tetrakis-diethylamido-titanium or a composition thereof, not being limited thereto, may be provided into the evaporation space 150 of the evaporator 100. As illustrated above, a carrier gas cyclone may be generated to evaporate the precursor in the evaporation space 150. The evaporated precursor may be provided via the outlet 170 into the process chamber 40 to form the floating gate layer 320 on the structure. Ligands may depart from the central metal in the precursor and may be emitted outside of the process chamber 40 together with the carrier gas. When the central metal may be deposited on the structure, e.g., a titanium layer may be formed as the floating gate layer 320.

The dielectric layer 330 may be formed to include a high-k material, e.g., aluminum oxide, hafnium oxide, lanthanum oxide, hafnium aluminum oxide, titanium oxide, tantalum oxide, zirconium oxide or a composition thereof, not being limited thereto, by a deposition process such as a CVD process or an ALD process. The dielectric layer 330 may be also formed by the method of forming a layer illustrated with reference to FIG. 7 using the deposition apparatus 50 and an evaporator 100 illustrated with reference to FIGS. 1 to 6.

For example, a precursor including organic metal including zirconium such as TEMAZ or organic metal including hafnium such as tetrakis-ethylmethylamido-hafnium may be used. The evaporated precursor may be provided into the process chamber 40 using the above-illustrated apparatus together with an oxidative material, e.g., ozone gas, oxygen gas or a composition thereof, not being limited thereto. Thus, the dielectric layer 330 including hafnium oxide or zirconium oxide, etc.

The control gate layer 340 may be formed to include polysilicon and/or a metal or a metal nitride, e.g., titanium, titanium nitride, tantalum, tantalum nitride or a composition thereof, not being limited thereto by a deposition process such as a CVD process, an ALD process or a sputtering process. The control gate layer 340 may be also formed by the method of forming a layer illustrated with reference to FIG. 7 using the deposition apparatus 50 and an evaporator 100 illustrated with reference to FIGS. 1 to 6.

For example, a precursor including titanium such as tetrakis-dimethylamido-titanium, tetrakis-diethylamido-titaniumz, etc. or organic metal including tantalum may be used. The evaporated precursor may be provided into the process chamber 40 using the above-illustrated apparatus together with a reactant, e.g., ammonia gas, nitric oxide gas, nitrous oxide gas or a composition thereof, not being limited thereto. Thus, the control gate layer 340 including a conductive material, e.g., titanium nitride, tantalum nitride or a composition thereof, not being limited thereto, may be formed.

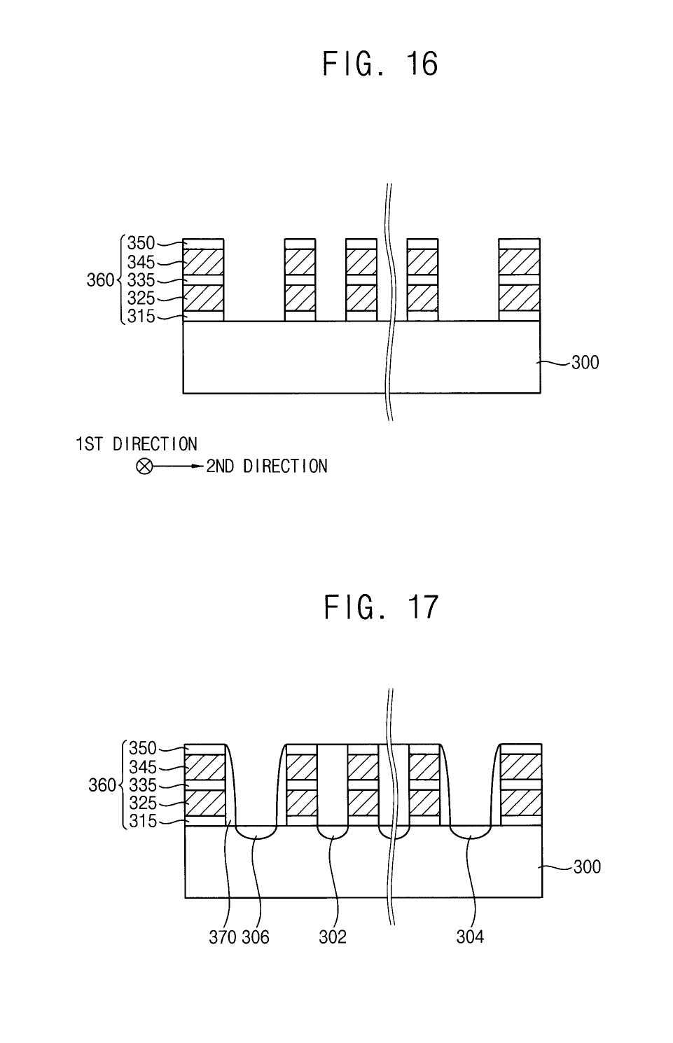

Referring to FIG. 16, a hard mask 350 may be formed on the control gate layer 340, and the control gate layer 340, the dielectric layer 330, the floating gate layer 320 and the tunnel insulation layer 310 may be etched using the hard mask 350 as an etching mask to form a plurality of gate patterns 360. The gate pattern 360 may include a tunnel insulation layer pattern 315, a floating gate 325, a dielectric layer pattern 335, a control gate 345 and a hard mask 350 sequentially stacked on the substrate 300.

Each gate pattern 360 may extend in a first direction, and the plurality of gate patterns 360 may be disposed in a second direction substantially perpendicular to the first direction.

The plurality of gate patterns 360 may include a cell gate pattern, a ground selection line (GSL) and a string selection line (SSL), which may define a string. According to an exemplary embodiment, the string may include a plurality of cell gate patterns, e.g., 16 or 32 cell gate patterns, the GSL may be disposed near one of an outermost cell gate patterns, and the SSL may be disposed near another of the cell gate patterns.

Referring to FIG. 17, a spacer layer may be formed on the substrate 300 to cover the gate patterns 360, and the spacer layer may be anisotropically etched to form a spacer 370 at a sidewall of the gate pattern 360. Thus, a gate structure including the gate pattern 360 and the spacer 370 may be formed.

An ion implantation process using the gate structure as an ion implantation mask may be performed to form first, second and third impurity regions 302, 304 and 306 at upper portions of the substrate 300 adjacent to the gate structure.

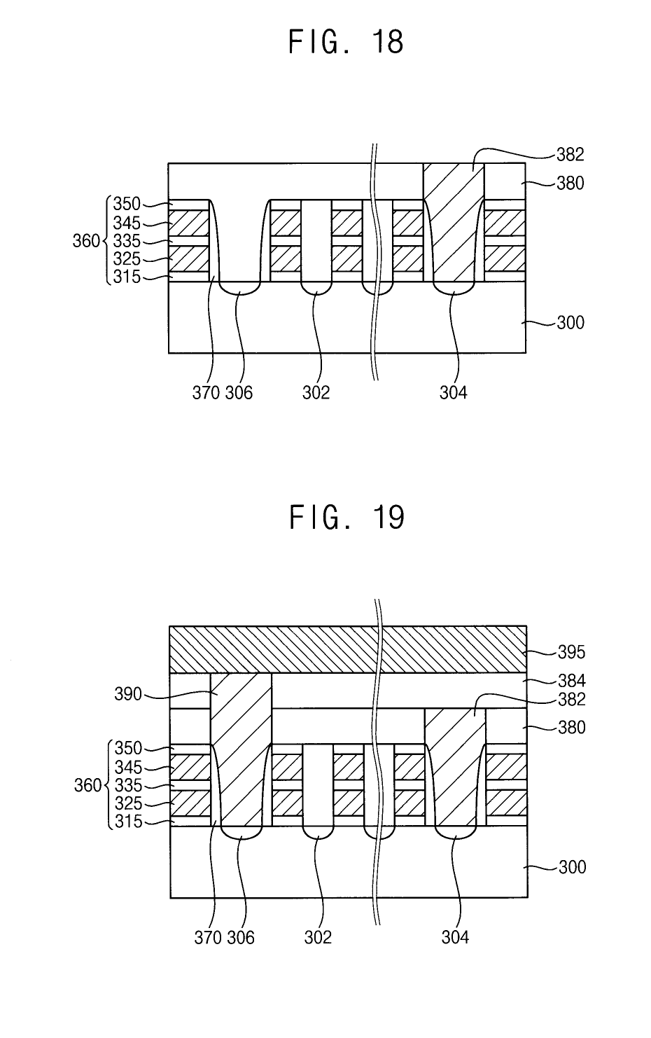

Referring to FIG. 18, a first insulating interlayer 380 may be formed on the substrate 300 to cover the gate structure. The first insulating interlayer 380 may be formed to include an oxide, e.g., boron phosphorus silicate glass (BPSG), undoped silicate glass (USG) or spin on glass (SOG), not being limited thereto, by a deposition process such as a CVD process, an ALD process or a sputtering process.

A first opening (not shown) may be formed through the first insulating interlayer 380 to expose the second impurity region 304, and a first conductive layer may be formed on the substrate 300 and the first insulating interlayer 380 to fill the first opening. The first conductive layer may be formed to include doped polysilicon, a metal or a metal silicide. The first conductive layer may be planarized until a top surface of the first insulating interlayer 380 may be exposed to form a common source line (CSL) 382 filling the first opening and making contact with the second impurity region 304.

Referring to FIG. 19, a second insulating interlayer 384 may be formed on the first insulating interlayer 380 and the CSL 382. The second insulating interlayer 384 may be formed to include an oxide, e.g., BPSG, USG or SOG, not being limited thereto, by a deposition process such as a CVD process, an ALD process or a sputtering process.

A second opening (not shown) may be formed through the first and second insulating interlayers 380 and 384 to expose the third impurity region 306, and a second conductive layer may be formed to include doped polysilicon, a metal or a metal silicide. The second conductive layer may be planarized until a top surface of the second insulating interlayer 384 may be exposed to form a bit line contact 390 filling the second opening and making contact with the third impurity region 306.

A third conductive layer may be formed on the second insulating interlayer 384 and patterned to form a bit line 395 electrically connected to the bit line contact 390 and extending in the second direction. The third conductive layer may be formed to include doped polysilicon, a metal or a metal silicide.

By the above-illustrated process, the flash memory device in accordance with an exemplary embodiment may be manufactured.

Measuring a Contact Angle Between a Droplet and a Metal Layer Before and after a Treatment on the Metal Layer

After dropping a droplet of TEMAZ solution having been prepared by mixing TEMAZ and ethanol solvent onto a stainless steel plate, a contact angle between the droplet and the top surface of the stainless steel plate was measured (before forming a liquid-repellent layer).

Cyclic polysiloxane represented by chemical formula 4 and Tetrahydrofuran (THF) solvent were mixed to form a mixture, and the mixture was spray coated on a stainless steel plate to form a liquid-repellent layer. A droplet of TEMAZ solution substantially the same as the above was dropped onto the liquid-repellent layer, and a contact angle between the droplet and the top surface of the liquid-repellent layer was measured (after forming a liquid-repellent layer). The contact angles were compared to each other. The experiment was performed on three different stainless steel plates (SUS 301, SUS 304 and SUS 316). The experimental result was shown in Table 1.

TABLE 1

| | before forming a liquid- | after forming a liquid- |
|---|---|---|
| | repellent layer | repellent layer |
| SUS 301 | 88° | 121° |
| SUS 304 | 88° | 122° |
| SUS 316 | 77° | 130° |

As shown in Table 1, after forming the liquid-repellent layer, the contact angle was increased to at least 90° on all of the three stainless steel plates. That is, the contact angle may be increased by the treatment, and the surface energy may be decreased. Thus, non-evaporated precursor may be prevented from contaminating the inner wall of the evaporator by the treatment.

The above evaporator for precursor and the method of forming a layer using the same may be applied to forming dielectric layers or conductive layers in various types of semiconductor devices, e.g., DRAMs, flash memory devices, logic devices, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the inventive concept. Accordingly, all such modifications are intended to be included within the scope of the inventive concept as defined in the claims.

What is claimed is:

1. An evaporator for a precursor, comprising:
a main body;
an evaporation space in the main body, the evaporation space comprising a first evaporation space and a second evaporation space in communication with the first evaporation space, the first evaporation space comprising a conical shape portion and the second evaporation space comprising a hollow cylindrical shape portion;
a precursor inlet through which a precursor is provided into a front portion of the first evaporation space corresponding to an apex of the conical shape portion;
at least one carrier gas inlet through which a carrier gas is provided into the first evaporation space, the carrier gas inlet penetrating the main body and extending in a substantially tangential direction with respect to a sidewall of the first evaporation space at the conical shape portion; and
an outlet through which the precursor is emitted, the outlet being in fluid communication with an end portion of the second evaporation space.

2. The evaporator of claim 1, further comprising a heater surrounding the main body.

3. The evaporator of claim 1, wherein the precursor inlet penetrates the main body and is in fluid communication with the front portion of the first evaporation space.

4. The evaporator of claim 3, wherein a contact angle between the precursor inlet and the sidewall of the first evaporation space at the conical shape portion is in a range of about 105 to about 120°.

5. The evaporator of claim 1, wherein the at least one carrier gas inlet comprises first and second carrier gas inlets, and
wherein a line connecting end portions of the first and the second carrier gas inlets corresponds to a diameter of a cross-section of the first evaporation space at the conical shape portion.

6. The evaporator of claim 1, wherein the outlet includes a protrusion extending toward an inside of the second evaporation space.

7. The evaporator of claim 6, wherein the outlet is detachably inserted into the inside of the second evaporation space.

8. The evaporator of claim 6, wherein a ratio of a diameter of the second evaporation space at the hollow cylindrical portion to a diameter of the outlet is in a range of about 5 to about 8.

9. The evaporator of claim 1, wherein an inner wall of the evaporation space is treated, thereby becoming liquid-repellent.

10. The evaporator of claim 9, further comprising a liquid-repellent layer on the inner wall of the evaporation space.

11. The evaporator of claim 10, wherein the liquid-repellent layer comprises a fluorine substituted silane.

12. The evaporator of claim 9, wherein the evaporation space has minute bumps on the inner wall thereof.

13. The evaporator of claim 1, wherein a ratio of a length of the second evaporation space to a length of the first evaporation space in a direction extending from the precursor inlet to the outlet is about 8 to about 12.

14. A method of forming a layer, comprising:
loading a substrate into a process chamber;
providing a carrier gas heated to a given temperature range into a first evaporation space via at least one carrier gas inlet to form a carrier gas cyclone, the first evaporation space comprising a conical shape portion, and the carrier gas inlet extending in a substantially tangential direction with respect to a sidewall of the first evaporation space at the conical shape portion;
providing a precursor to a front portion of the first evaporation space corresponding to an apex of the conical shape;
evaporating the precursor by circulating the precursor via the carrier gas cyclone in a second evaporation space in fluid communication with the first evaporation space; and
providing the evaporated precursor onto the substrate in the process chamber via an outlet at an end portion of the evaporator.

15. The method of claim 14, further comprising providing a protrusion to the outlet such that the outlet extends toward an inside of the second evaporation space, whereby a non-evaporated portion of the precursor is trapped at the protrusion.

16. An evaporator for a precursor, comprising:
a main body;
an evaporation space in the main body, the evaporation space comprising a curved surface portion;
a precursor inlet through which a precursor is injected into the evaporation space;
at least one carrier gas inlet through which a carrier gas is injected into the evaporation space, the carrier gas inlet being configured to inject the carrier gas into the evaporation surface such that the injected carrier gas circulates along the curved surface and progresses along with the precursor; and
an outlet which is connected to the second evaporation space and through which the precursor evaporated in the evaporation space is emitted.

17. The evaporator of claim 16, wherein an inner wall of the evaporation space is treated, thereby becoming liquid-repellent.

18. The evaporator of claim 17, wherein the carrier gas inlet is connected to the curved surface so that the injected carrier gas injected from the carrier gas inlet circulates along the curved surface in the first evaporation space, and
wherein the carrier gas inlet is configured to inject the carrier gas into the first evaporation in a substantially tangential direction with respect to the curved surface.

19. The evaporator of claim 16,
wherein the carrier gas inlet is connected to the curved surface so that the injected carrier gas injected from the carrier gas inlet circulates along the curved surface in the first evaporation space, and
wherein the carrier gas inlet is configured to inject the carrier gas into the first evaporation in a substantially tangential direction with respect to the curved surface.

20. The evaporator of claim 16, the outlet includes a protrusion extending toward an inside of the second evaporation space, and
wherein the outlet is detachably inserted into the inside of the second evaporation space.
